(19) United States
(12) Patent Application Publication
(10) Pub. No.: US 2002/0043702 A1
(43) Pub. Date: Apr. 18, 2002

(54) Semiconductor package comprising substrate with mounting leads and manufacturing method therefor

(75) Inventors: Jae-Hong Kim, Chungcheongnam-do (KR); Yong-An Kwon, Chungcheongnam-do (KR)

Correspondence Address: MARGER JOHNSON & McCOLLOM, P.C., 1030 S.W. Morrison Street, Portland, OR, 97205, US

(73) Assignee: Samsung Electronics Co., Ltd., Suwon-city (KR)

(21) Appl. No.: 09/957,888

(22) Filed: Sep. 20, 2001

(30) Foreign Application Priority Data
Oct. 16, 2000 (KR) 2000-60679

(51) Int. Cl. H01L 23/495

(52) U.S. Cl. 257/666

(57) ABSTRACT

A semiconductor chip package comprising a substrate with mounting leads and a manufacturing method thereof are provided. The semiconductor chip package comprises a substrate having a lower surface and an upper surface. A semiconductor chip with a plurality of bonding pads on an active surface is disposed on the upper surface of the substrate. The substrate includes a plurality of electrode pads on the upper surface and electrode terminals on the sides of the lower surface. Each of said electrode pads is electrically connected to a corresponding one of bonding pads and each of said electrode terminals is electrically connected to a corresponding one of the electrode pads. Further, the package includes a plurality of mounting leads, each having one end electrically connected to a corresponding one of said electrode terminals and the other end extending outwardly from the substrate to serve as external connection terminals.

With the structure of the present invention, the failures due to the formation of the solder balls can be prevented.

### RELATED APPLICATION

This application relies for priority upon Korean Patent Application No. 2000-0060679, filed on October 16, the contents of which are herein incorporated by reference in their entirety.

### BACKGROUND OF THE INVENTION

1. Field of the Invention

The present invention relates to the field of semiconductor packaging technology and, more particularly, to a semiconductor package comprising a substrate with mounting leads and a manufacturing method thereof.

2. Description of the Related Art

In the conventional plastic package, a semiconductor chip is mounted on the lead frame and encapsulated with a molding compound such as Epoxy Molding Compound (EMC) to form a package body. FIG. 1 is a cross-sectional view of the conventional plastic package.

As shown in FIG. 1, the semiconductor chip package 100 comprises a lead frame 20 having a die pad 22, a plurality of inner leads 24 and a plurality of outer leads 26. After mounting a semiconductor chip 10 on the die pad 22, bonding pads 12 of the semiconductor chip 10 are electrically connected to the inner leads 24 typically by bonding wires 30. The semiconductor chip 10, the die pad 22 and inner leads 24 are encapsulated with a molding compound 40 such as EMC to form a package body as discussed. The outer leads 26 extending from the package body are formed to be suitably mounted on external electronic devices.

Under international standards organizations, i.e. JEDEC (Joint Electron Device Engineering Council), plastic packages are standardized in type, size and number of outer leads, and it is difficult to modify design of the semiconductor chip.

In order to deal with such a difficulty, numerous attempts have been made to develop new types of packages having a substrate. The leader of these new types of packages is a BGA package. FIG. 2 is a cross-sectional view of the conventional BGA package, and FIG. 3 illustrates a manufacturing method of the BGA package illustrated in FIG. 2.

As shown in FIG. 2 and FIG. 3, a conventional BGA package 200 comprises a substrate 150. A semiconductor chip 110 is mounted on the substrate 150, and bonding pads 112 of the semiconductor chip 110 are electrically connected to electrode pads (not shown) of the substrate 150 by bonding wires 130. The semiconductor chip 110 on the upper surface of the substrate 150 is molded. A plurality of electrode terminals (not shown), i.e. solder pads, are formed on the lower surface of the substrate 150. The electrode terminals on the lower surface are electrically connected to the electrode pads on the upper surface, and each of the solder balls 160 is attached to a corresponding one of the solder pads. The solder balls serve as external connection terminals.

Since this BGA package is mounted on external electronic devices using the solder ball formed on the lower surface, the area it occupies is the same as the size of the substrate 150.

The manufacturing method of the BGA package 200 is illustrated in FIG. 3. The method typically consists of preparing a substrate having electrode pads corresponding to the bonding pads of the chip on an upper surface, and solder pads electrically connected to the electrode pads on a lower surface (step 182); mounting the semiconductor chip on the chip-receiving region of the substrate (step 184); electrically interconnecting the semiconductor chip to the substrate by the bonding wire (step 186); molding the semiconductor chip on the upper surface of the substrate (step 188); attaching a plurality of solder balls on the lower surface of the substrate (step 190); and forming external connection terminals (192).

Differing from the conventional plastic package using the lead frame, since the BGA package uses solder balls, the steps of attaching and reflowing the solder balls must be included. However, these steps can cause a variety of failures.

Foremost, the steps cause misalignment of the solder ball on the electrode terminal, i.e. the solder pad. As a result, in order to detect misalignment of the solder ball after attachment to the solder pad a tester is used to determine whether or not the solder ball is properly attached to the solder pad. This complicates the manufacturing process and leads to higher manufacturing costs.

Additionally, during IR reflowing the solder balls, the solder of the solder balls melts and flows, further weakening the connection between the solder ball and the solder pads of the substrate.

### SUMMARY OF THE INVENTION

Accordingly, an object of the present invention is to prevent failures from occurring at the step of attaching the solder balls to the substrate and the step of reflowing the solder balls.

The foregoing and other objects of the present invention are provided by a semiconductor chip package comprising a semiconductor chip having a plurality of bonding pads on an active surface; a substrate having a chip-receiving region and a plurality of electrode pads on an upper surface and electrode terminals on the sides of a lower surface, each of the electrode pads corresponding to one of the bonding pads and each of the electrode terminal corresponding to one of the electrode pads; connection means for electrically interconnecting the bonding pads to the electrode pads; a molding compound for molding the semiconductor chip to the connection means, and the electrode pads on the upper surface of the substrate; and a plurality of mounting leads, each having one end electrically connected to a corresponding one of the electrode terminals and the other end extending outwardly from the substrate. The mounting leads serve as external connection terminals. The mounting leads are arranged in parallel to the substrate and each of the one ends of the mounting leads is attached to a corresponding one of the electrode terminals.

In another aspect of the present invention, a method for manufacturing a semiconductor chip package comprising a substrate with mounting leads is described. The manufacturing method comprises preparing a substrate with a plurality of electrode pads and a plurality of electrode terminals, mounting a semiconductor chip on a chip-receiving region of the substrate, molding the semiconductor chip, the connection means, and the electrode pads on an upper surface of the substrate, attaching a lead frame having a plurality of mounting leads to a lower surface of the substrate, and separating the mounting leads from the lead frame, thereby obtaining a semiconductor chip package.

### BRIEF DESCRIPTION OF THE DRAWINGS

These and other objects, features and advantages of the present invention will be readily understood with reference to the following detailed description provided in conjunction with the accompanying drawings, wherein like reference numerals designate like structural elements and, in which:

FIG. 1 is a cross-sectional view showing a conventional plastic package;

FIG. 2 is a cross-sectional view showing a conventional BGA package;

FIG. 3 is a flow chart illustrating a manufacturing method for the BGA package of FIG. 2;

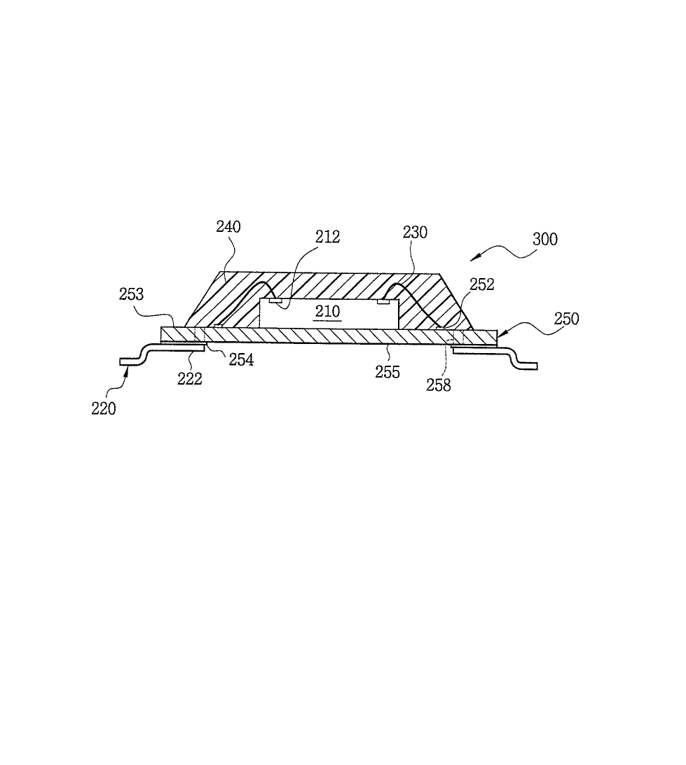

FIG. 4 is a cross-sectional view showing a semiconductor chip package in accordance with an embodiment of the present invention;

FIG. 5 is a flow chart illustrating a manufacturing method for the semiconductor chip package of FIG. 4;

FIG. 6a through FIG. 6e are views showing each step of the manufacturing method of FIG. 5;

FIG. 7a is a perspective view of one substrate of the present invention;

FIG. 7b is a perspective view of another substrate of the present invention; and

FIG. 8a through FIG. 8c are front views showing the forms possible for the mounting leads of the present invention.

### DETAILED DESCRIPTION OF THE PREFERRED EMBODIMENTS

Preferred embodiments of the present invention will be described below with reference to the accompanying drawings.

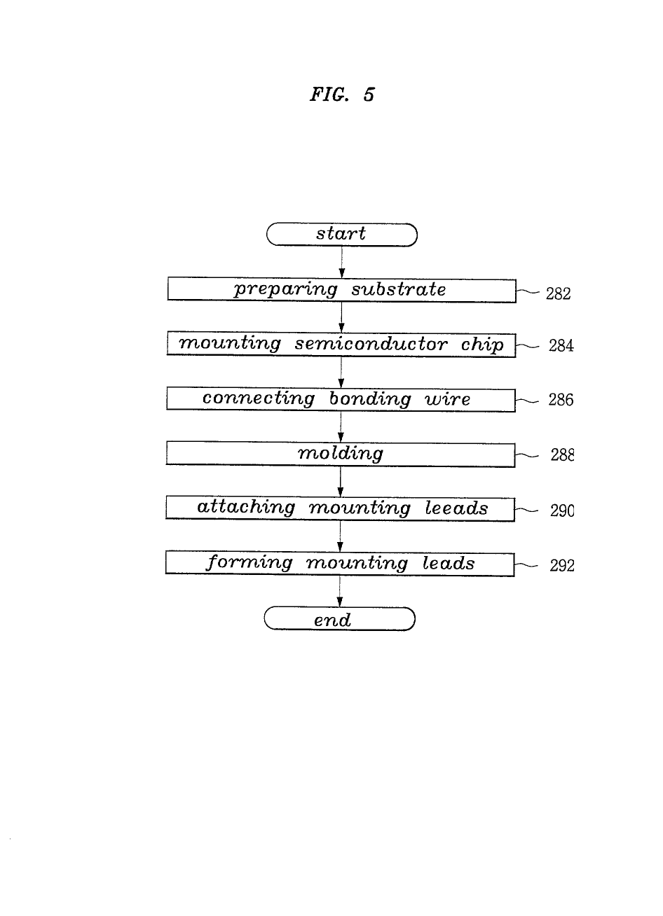

FIG. 4 is a cross-sectional view of a semiconductor chip package 300 in accordance with an embodiment of the present invention.

As shown in FIG. 4, the semiconductor chip package 300 comprises a substrate 250 with mounting leads 220. The substrate 250 is preferably formed of an organic material, e.g., BT (Bismaleimide-Triazine) resin or epoxy glass (also referred to as ‘FR-4’). A semiconductor chip 210 is mounted on an upper surface 253 of the substrate 250. Bonding pads 212 of the semiconductor chip 210 are electrically connected to electrode pads 252 on the substrate 250 by a bonding wire 230. However, a person skilled in the art will appreciate that other suitable connection means can be used to electrically connect the bonding pads 212 to the electrode pads 252. The semiconductor chip 210, the bonding wire 230, and the electrode pads 252 on the upper surface 253 of the substrate 250 are covered with a molding compound 240 such as epoxy molding compound (EMC). A plurality of via holes 258 are formed through the substrate 250, and the electrode pads 252 on the upper surface 253 are electrically connected (not shown for the sake of simplicity) to the electrode terminals 254 on the lower surface 255 through the via holes 258.

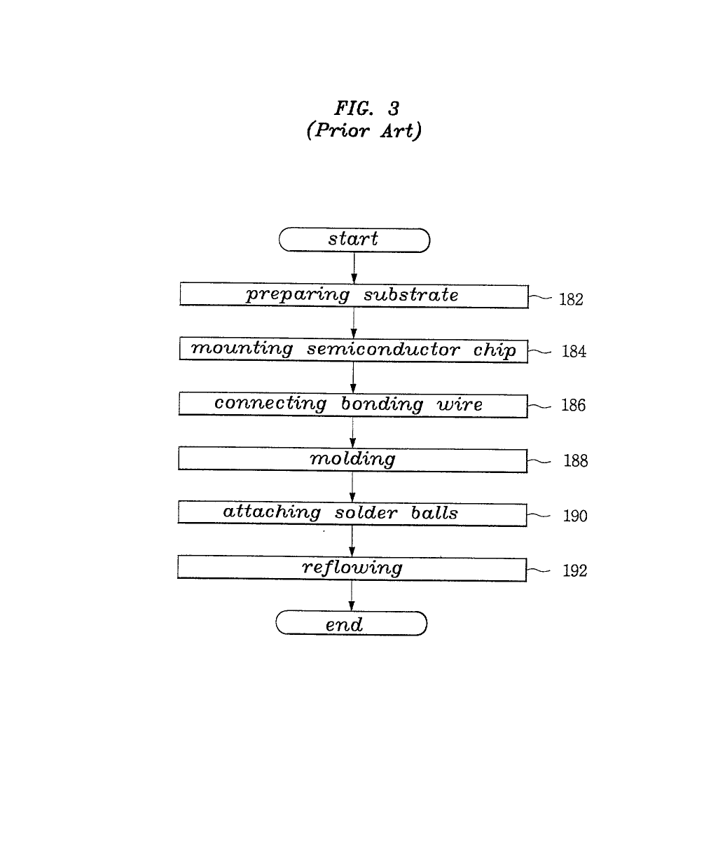

Differing from the conventional BGA package having the solder balls (160 in FIG. 2) on the lower surface of the substrate, the present invention comprises the mounting leads 220 attached to the electrode terminals 254 on the lower surface 255 of the substrate 250.

The substrate 250 comprises metal traces (not shown) on the upper and the lower surfaces. The metal traces are connected to the electrode pads 252 and the electrode terminals 254. The electrode pads 252 are electrically connected to the electrode terminals 254 through the via holes 258. By forming at least one metal wiring layer within the substrate 250, the arrangements (designs) of the electrode pads 252 and the electrode terminals 254 can be easily modified.

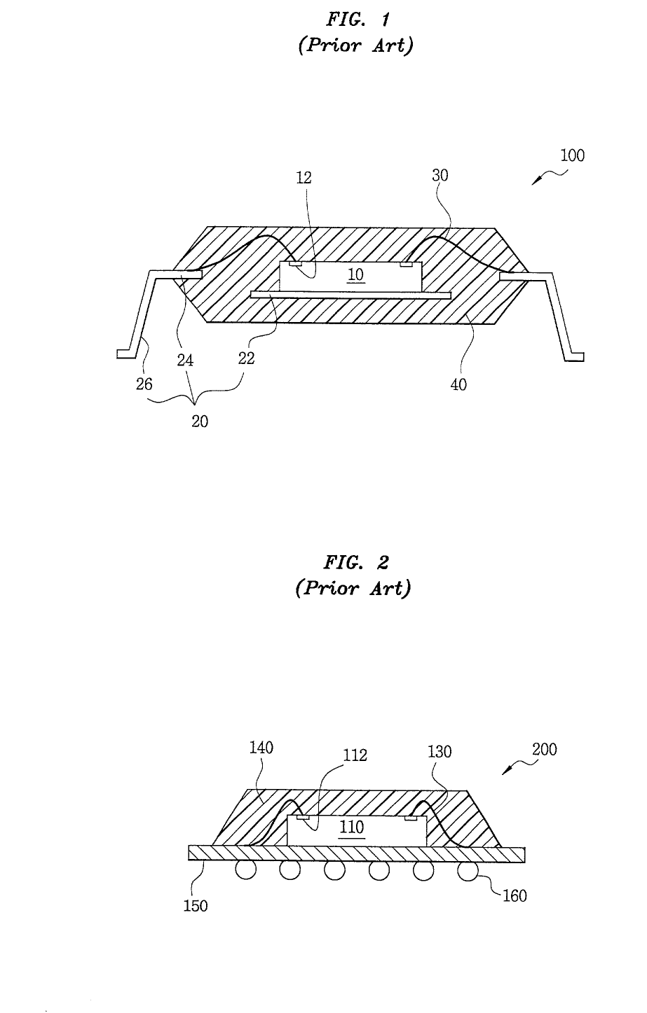

Unlike the lead frame (20 in FIG. 1) of the conventional plastic package, the mounting leads 220 of the present invention in a frame shape do not require a die pad and inner leads. The mounting leads 220 are easily produced by a stamping method. With this method, the pitch between neighboring mounting leads 220 is made finer and the number of the mounting leads in a limited size can be increased. Before attaching the mounting leads 220 to the lower surface 255 of the substrate 250, mounting leads 220 are plated with a high-conductivity material to improve the conductivity of the package.

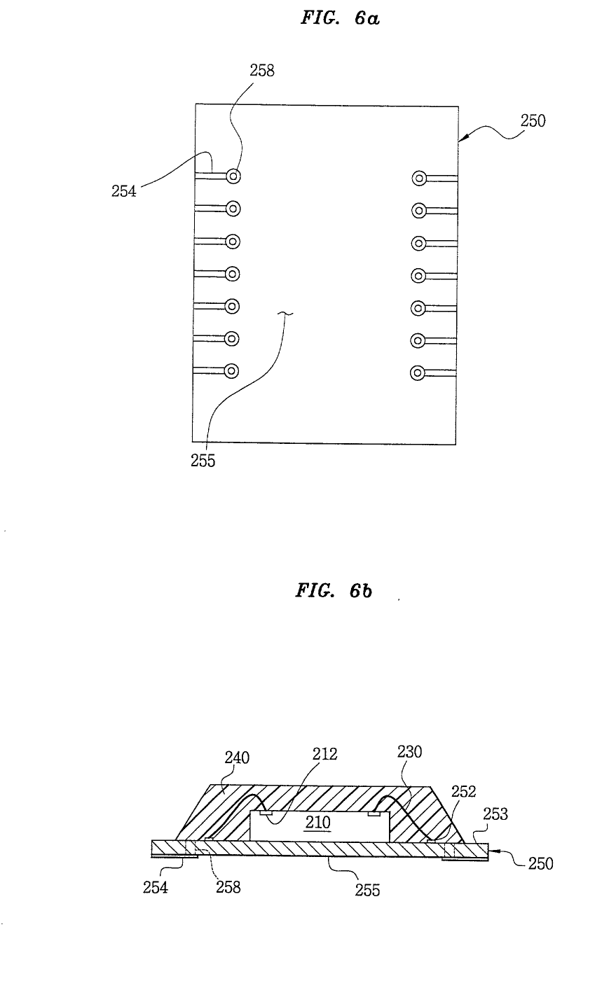

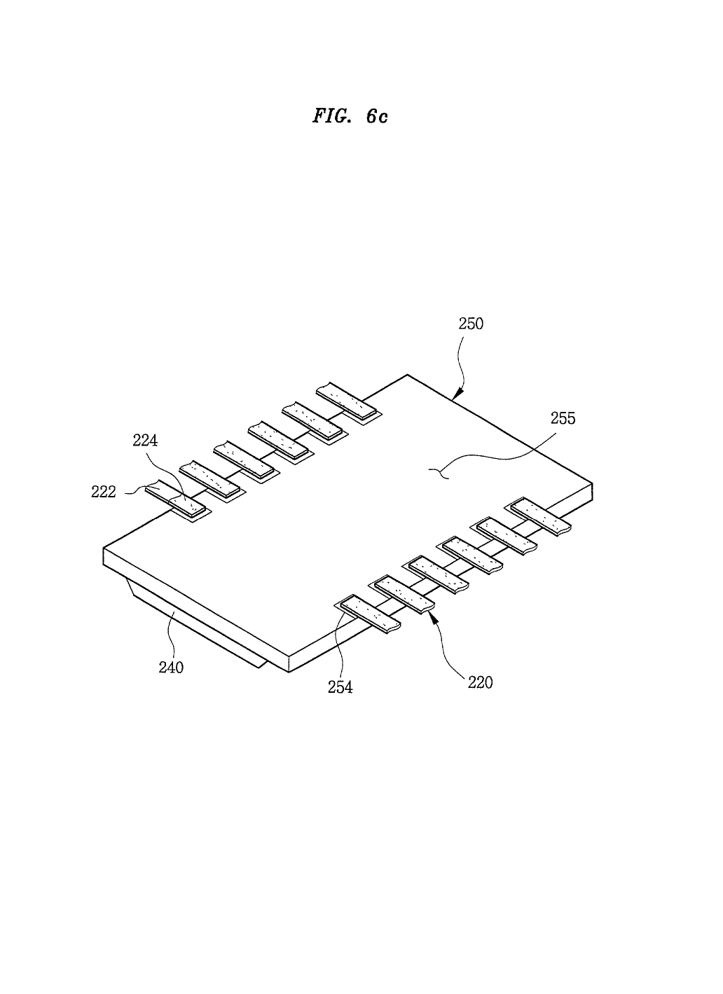

FIG. 5 is a flow chart illustrating a manufacturing method of the semiconductor package of FIG. 4. FIG. 6a through FIG. 6e show each step of the manufacturing method of FIG. 5. With reference to FIG. 5 through FIG. 6e, the manufacturing method of the semiconductor chip package according to the present invention is described below.

The semiconductor chip package 300 is manufactured by a series steps of preparing the substrate (step 282), mounting the semiconductor chip (step 284), connecting the bonding wire (step 286), molding the semiconductor chip on the upper surface of the substrate (288), attaching the mounting leads to the lower surface of the substrate (290), and forming the mounting leads (292).

As shown in FIG. 6a, the substrate 250 is prepared. A plurality of the electrode terminals 254 are arranged on the lower surface 255 of the substrate 250 along the opposing sides of the substrate 250. Each electrode terminal 254 is electrically connected to a corresponding one of the electrode pads 252 on the upper surface 253 through the via hole 258.

As shown in FIG. 6b, the semiconductor chip 210 is mounted on the upper surface 253 of the substrate 250 by an adhesive, and the bonding pads 212 of the semiconductor chip 210 are electrically connected to the electrode pads 252 of the substrate by the bonding wire 230. The semiconductor chip 210, the bonding wires 230, and the electrode pads 252 on the upper surface 253 are covered with a molding compound such as EMC.

Herein, the substrate 250 is a single layered substrate, which does not comprise any metal layer within the substrate 250. However, a multi-layered substrate, which comprises at least a single metal layer, may be used. In case of the multi-layered substrate, the electrode pads on the upper surface and the electrode terminals on the lower surface can be easily modified according to the design of the semiconductor chip.

As shown in FIG. 6c, the mounting leads 220 are attached to the lower surface 255 of the substrate 250. The mounting leads 220 are treated as a frame type, and one end of the mounting leads 220 is attached to the electrode terminal 254 of the substrate 250 and the other end of the mounting leads 220 extends from the substrate 250. As described above, the mounting leads 220 are preferably plated with a conductive material to form a plating layer 224 to improve the conductivity of the semiconductor chip package.

As shown in FIG. 6d, after placing the mounting leads 220 on the electrode terminals 254, the package 240 is interposed within mold dies 310, 312 and thermocompressed. The mold dies 310, 312 comprise a support block 312 for supporting the upper surface of the substrate and a heat block 310 for pressing the mounting leads 220. The mounting leads 220 are electrically connected to the electrode terminals 254 by heat emitted from the heat block 310. A conductive adhesive material (not shown) is interposed between the electrode terminals 254 and the mounting leads 220 to improve the adhesion between the electrode terminals 254 and the mounting leads 220.

As shown in FIG. 6e, the mounting leads 220 are formed to be suitably mounted on external electronics by using upper and lower forming dies 320, 322 and a forming means 324. After fixing the semiconductor chip package between the upper forming die 322 and the lower forming die 320, the extending ends of the mounting leads are bent to the desired shape with the forming means 324.

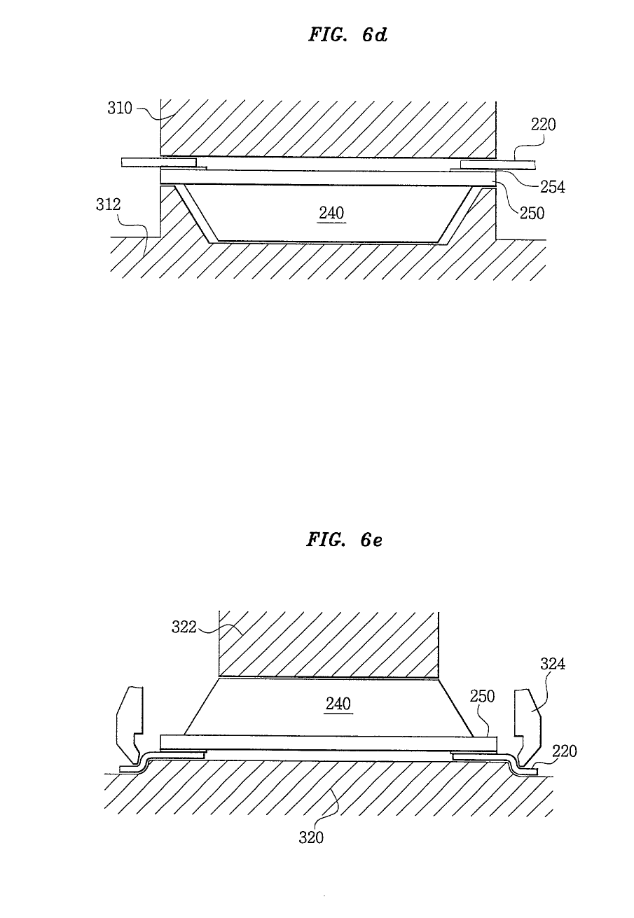

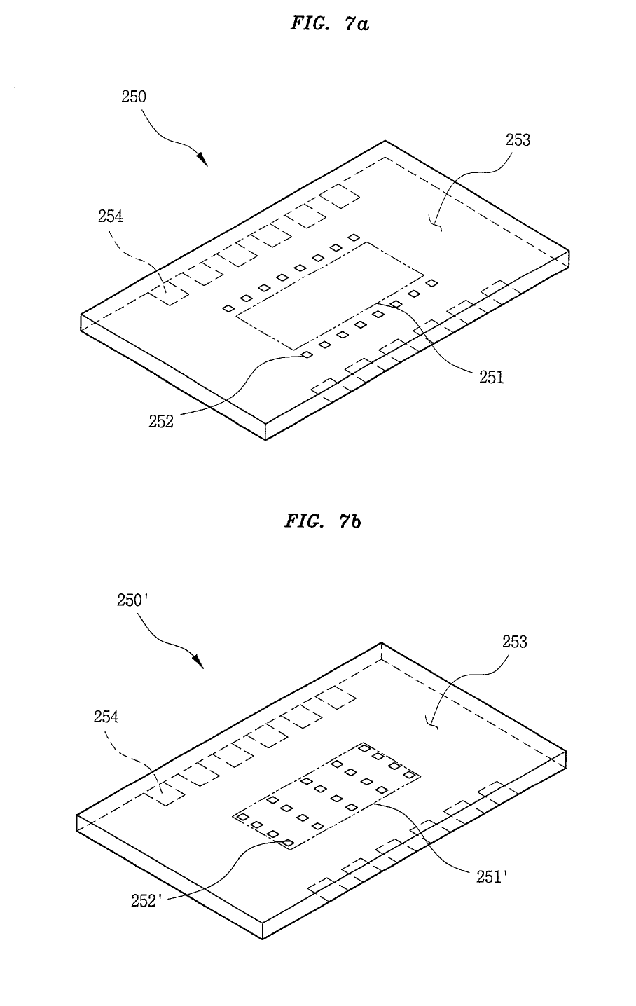

FIG. 7a shows one example of a substrate of the present invention, and FIG. 7b shows another example of a substrate of the present invention.

The substrate 250 of FIG. 7a is used for a semiconductor chip of the edge pad type. A plurality of electrode pads 252 are arranged on opposing sides outside of the perimeter of a chip-receiving region 251 of the upper surface 253. The substrate 250′ of FIG. 7b is used for a semiconductor chip using a flip-chip bonding technique. A plurality of electrode pads 252′ are arranged in a lattice shape on a chip-receiving region 251′ of the upper surface 253′.

The substrate 250 of FIG. 7a is applied to the semiconductor chip package of FIG. 4. The substrate 250′ of FIG. 7b is applied to a semiconductor chip package using a flip chip bonding technique. After mounting the semiconductor chip on the chip-receiving region 251′ using bumps (not shown), the semiconductor chip and the bumps on the upper surface are encapsulated (molded) and the mounting leads 220 are attached to the lower surface of the substrate.

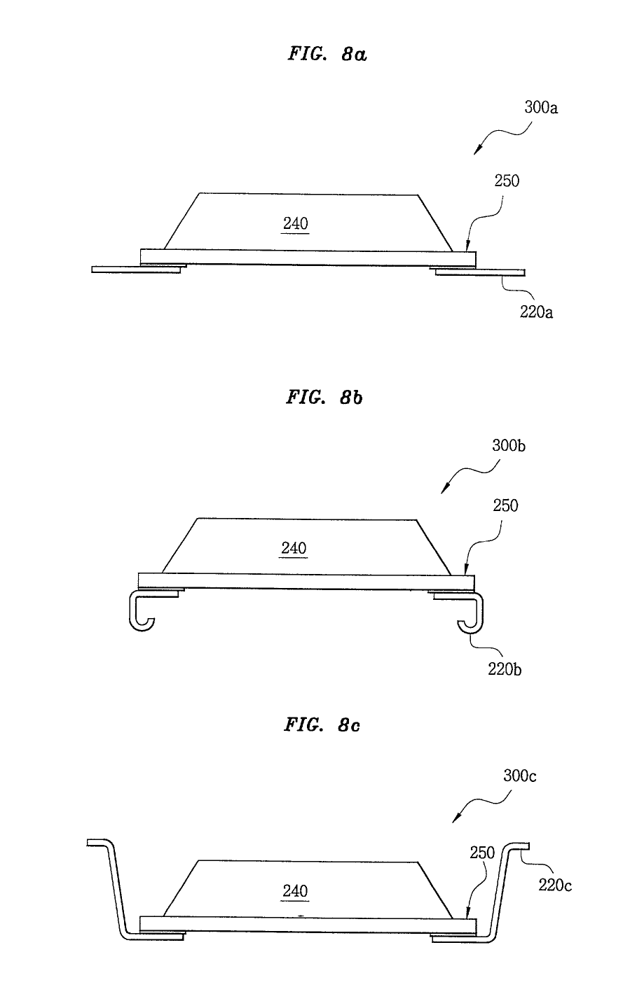

The mounting leads 220 of FIG. 4 may be formed in gull-wing shape the same as the conventional plastic package. FIG. 8a through FIG. 8c show the various respectively formed shapes of the mounting leads. Mounting leads 220a of FIG. 8a are not formed, mounting leads 220b of FIG. 8b are formed in a “J” shape, and mounting leads 220c of FIG. 8c are formed in a reversed shape.

As shown in FIG. 8a, the mounting leads 220a are not bent. In other words, the mounting leads 220a extends substantially in the plane of the lower surface of the substrate 250 along their extent. This shape minimizes the height of the semiconductor chip package and the pitch between the neighboring leads, thereby increasing the number of the mounting leads. As shown in FIG. 8b, the J-shaped mounting leads 220b reduce the mounting area of the semiconductor chip package.

Accordingly, the semiconductor chip package of the present invention comprises providing the substrate with mounting leads rather than solder balls, thereby preventing failures due to the use of the solder balls described above.

Since the present invention uses not the solder balls but the mounting leads as the external connection terminals, the problems due to formation of the solder balls, i.e. misalignment of the solder ball on the solder pad, flow-down of the molten solder from the solder balls, or imperfect connection between the solder ball and the solder pad can be prevented.

The conventional plastic package has drawbacks in that as the design of semiconductor chip changes, the structure of the lead frame must be modified, and therefore the mold die of the lead frame is also changed. In contrast, since the package of the present invention utilizes the exposed substrate, it has an advantage in that the metal wiring on the substrate can be modified by a comparatively easier step such as a mask change.

Further, since the semiconductor chip package of the present invention is the same as the conventional plastic package in appearance, the present invention can use the same printed circuit board (PCB), as it is, which is used on the conventional plastic package.

Although the preferred embodiments of the present invention have been described in detail hereinabove, it should be understood that many variations and/or modifications of the basic inventive concepts that appear to those skilled in the art will still fall within the spirit and scope of the present invention as defined in the appended claims.

What is claimed is:

1. A semiconductor chip package comprising:
a substrate having a lower surface and an upper surface,
a semiconductor chip with a plurality of bonding pads on an active surface thereof, the chip disposed on the upper surface of the substrate;
wherein the substrate includes a plurality of electrode pads on the upper surface and electrode terminals on the sides of the lower surface, each of said electrode pads being electrically connected to a corresponding one of bonding pads and each of said electrode terminals being electrically connected to a corresponding one of the electrode pads;
a plurality of mounting leads, each having one end electrically connected to a corresponding one of said electrode terminals and the other end extending outwardly from the substrate to serve as external connection terminals.

2. The semiconductor chip package of claim 1, further comprising a molding compound for encapsulating said semiconductor chip and said electrode pads on the upper surface of said substrate.

3. The semiconductor chip package of claim 1, wherein said mounting leads are arranged in parallel to said substrate and each of said one end of said mounting leads is attached to a corresponding one of said electrode terminals.

4. The semiconductor chip package of claim 3, wherein said mounting leads are plated with a conductive material.

5. The semiconductor chip package of claim 1, wherein said other ends of said mounting leads extend substantially in the plane of the lower surface of the substrate along their extent.

6. The semiconductor chip package of claim 1, wherein said other ends of said mounting leads are bent in a gull-wing shape.

7. The semiconductor chip package of claim 1, wherein said other ends of said mounting leads are bent in a J-leaded shape.

8. The semiconductor chip package of claim 1, wherein a plurality of via holes are formed through said substrate, the via holes electrically connecting each of said electrode pads to a corresponding one of said electrode terminals.

9. The semiconductor chip package of claim 8, wherein at least one metal layer is formed within said substrate.

10. The semiconductor chip package of claim 1, wherein said bonding pads are electrically connected to said electrode pads using wire bonding.

11. The semiconductor chip package of claim 1, wherein said bonding pads are electrically connected to said electrode pads using a conductive bump.

12. The semiconductor chip package of claim 1, further comprising a conductive adhesive material interposed between the electrode terminals and the mounting leads.

13. A method for manufacturing a semiconductor chip package comprising:
(a) preparing a substrate having a lower surface and an upper surface, wherein a plurality of electrode pads are formed on the upper surface and wherein a plurality of electrode terminals are formed on sides of the lower surface, the electrode pads being electrically connected to corresponding electrode terminals;
(b) mounting a semiconductor chip on the upper surface of said substrate;
(c) encapsulating said semiconductor chip and said electrode pads on the upper surface of said substrate;
(d) attaching mounting leads on the electrode terminals, the mounting leads each having one end electrically connected to one of said electrode terminals and the other end extending outwardly from the substrate to serve as external connection terminals.

14. The manufacturing method of claim 13, after the step (d), further comprising benting the mounting leads to form a gull-wing shape or to form a J-leaded shape.

15. The manufacturing method of claim 13, before the step (d), further comprising plating said mounting leads with a conductive material.

16. The manufacturing method of claim 13, wherein in the step (d), one ends of said mounting leads are placed on said electrode terminals and attached to said electrode terminals by thermocompression.

17. A method for manufacturing a semiconductor chip package comprising:
preparing a substrate having a lower surface and an upper surface, wherein a plurality of electrode pads are formed on the upper surface and wherein a plurality of electrode terminals are formed on sides of the lower surface, the electrode pads being electrically connected to the corresponding electrode terminals through vias; and
attaching mounting leads on the electrode terminals, the mounting leads each having one end electrically connected to one of said electrode terminals and the other end extending outwardly from an outer perimeter of the lower surface of the substrate to serve as external connection terminals.

18. The method of claim 17, wherein said attaching mounting leads on the electrode terminals is performed utilizing a conductive adhesive.

19. The method of claim 17, further comprising, before attaching mounting leads,
mounting a semiconductor chip on the upper surface of said substrate;
encapsulating said semiconductor chip and said electrode pads on the upper surface of said substrate with a molding compound.
